(19) United States
(12) Patent Application Publication
(10) Pub. No.: US 2026/0038568 A1
(43) Pub. Date: Feb. 5, 2026

(54) MEMORY DEVICE HAVING WINDOW CENTERING

(71) Applicant: Micron Technology, Inc., Boise, ID (US)

(72) Inventors: Eric S. Carman, San Francisco, CA (US); Jordan Scott Belisle, Portland, OR (US)

(21) Appl. No.: 18/791,225

(22) Filed: Jul. 31, 2024

(51) Int. Cl. G11C 11/4074

(52) U.S. Cl. CPC G11C 11/4074

(57) ABSTRACT

A variety of applications can include an apparatus having a three-dimensional (3D) memory device with a mechanism for window centering for zeros and ones sensing. A 3D memory device can be constructed to implement a window centering scheme to add charge to the reference side of a sense amplifier such that a process window is centered between a voltage for a zero and a voltage for a one on a reference side of the sense amplifier. A 3D DRAM device can be constructed to selectively apply an idle bias to a local digit line, where the idle bias has a voltage in a range to optimize data retention or a reference voltage to the local digit line to bias the local digit line to a centering voltage.

### FIELD OF THE DISCLOSURE

Embodiments of the disclosure relate generally to electronic devices and systems, and more specifically, to memory devices, components of memory devices, operation of the memory devices, and formation thereof.

### BACKGROUND

Memory devices are typically provided as internal, semiconductor, integrated circuits in computers or other electronic devices. There are many different types of memory, including volatile and non-volatile memory. Volatile memory requires power to maintain its data, and includes random-access memory (RAM), dynamic random-access memory (DRAM), static RAM (SRAM), or synchronous dynamic random-access memory (SDRAM), among others. Non-volatile memory can retain stored data when not powered, and includes flash memory, read-only memory (ROM), electrically erasable programmable ROM (EEPROM), erasable programmable ROM (EPROM), resistance variable memory, such as phase-change random-access memory (PCRAM), resistive random-access memory (RRAM), magnetoresistive random-access memory (MRAM), or three-dimensional (3D) XPoint™ memory, among others. Properties of memory devices can be improved by enhancements to the design, operation, and fabrication of components of the memory devices.

### BRIEF DESCRIPTION OF THE DRAWINGS

The drawings, which are not necessarily drawn to scale, illustrate generally, by way of example, but not by way of limitation, various embodiments discussed in the present document.

FIG. 1 is a block diagram of components of an example three-dimensional dynamic random-access memory device implementing a control technique for a window for data access, in accordance with various embodiments.

FIG. 2 illustrates a cross-sectional view of an example three-dimensional dynamic random-access memory device having an array of memory cells, with the array coupled to a switch, in accordance with various embodiments.

FIG. 3 illustrates a cross-sectional view of an example three-dimensional dynamic random-access memory device having an array of memory cells, with the array coupled to a switch, and another array of memory cells, with the other array coupled to another switch, in accordance with various embodiments.

FIG. 4 illustrates an example procedural flow for window centering using a switch to provide a reference local digit line voltage to a reference local digit line for a data operation on a local digit line operation, in accordance with various embodiments.

FIG. 5 is a flow diagram of features of an example method of operating a three-dimensional dynamic random-access memory device, in accordance with various embodiments.

FIG. 6 is a flow diagram of an example method of forming a three-dimensional dynamic random-access memory device, in accordance with various embodiments.

FIG. 7 is a block diagram illustrating an example of a machine upon which one or more embodiments of one or more memory components may be implemented, in accordance with various embodiments.

### DETAILED DESCRIPTION

The following detailed description refers to the accompanying drawings that show, by way of illustration, various embodiments that can be implemented. These embodiments are described in sufficient detail to enable those of ordinary skill in the art to practice these and other embodiments. Other embodiments may be utilized, and structural, logical, mechanical, and electrical changes may be made to these embodiments. The term “horizontal” as used in this application is defined as a plane parallel to a conventional plane or surface of a wafer or substrate, regardless of the orientation of the wafer or substrate. The term “vertical” refers to a direction perpendicular to the horizontal as defined above. Various features can have a vertical component to the direction of their structure. The various embodiments are not necessarily mutually exclusive, as some embodiments can be combined with one or more other embodiments to form new embodiments. The following detailed description is, therefore, not to be taken in a limiting sense.

In a memory device, such as a 3D DRAM, data from a memory cell can be read using a sense amplifier (SA) coupled to a local digit line (LDL) to which the memory cell is coupled. A LDL operatively sensing data can be referred to as a data LDL. The SA can also be connected to a reference LDL. The SA can include a latch, where one side of the latch is connected to the data LDL and the other side of the latch is connected to the reference LDL. Ideally, the capacitances of the data LDL and the reference LDL should be exactly the same. In this case, when a positive charge or negative charge is dumped onto the data LDL and the reference LDL, the data LDL voltage would go above or below a reference by the same amount as the reference LDL. However, the reference LDL is not structured exactly the same as the data LDL. The reference LDL can be coupled to the SA by a global digit line (GDL) and the data LDL can be coupled to the SA by another GDL.

There is a mismatch of capacitance between the data LDL and the reference LDL. The reference LDL can be created by using a regular array for reference and using a LDL of the regular array as the reference LDL and coupling this LDL to the SA to which the data LDL is coupled, but without turning on an access line (WL) coupled to memory cells to which the reference LDL is coupled. There is a mismatch of capacitance between the data LDL and the reference LDL, since the reference LDL does not have a memory cell capacitance with the access transistor of the memory cell in the reference array turned off via an WL being at an off voltage. With differences in capacitances between the data LDL and the reference LDL, an imbalance is created in the sensing.

With a DRAM on, LDLs are set to an idle voltage. The idle digit line voltage (VBLD) is a reference voltage to hold and maintain retention of data. Typically, it is desired to have VBLD to be halfway between the voltage for a one and a voltage for a zero such as in a planar DRAM. However, for a 3D DRAM, better data retention occurs with VBLD set to a voltage that can be closer to the value of the voltage for a zero that is lower than the voltage for a one. This provides a larger ones margin to balance the margin between the ones retention and the zeros retention. The charge for ones that start at the ones voltage can leak with the voltage decreasing towards the LDL voltage and the voltage for zeros, initially at its set low voltage, can increase towards the LDL voltage. However, the rate of increase and decrease is not the same between the ones discharge and the zeros charge. For a determined voltage for setting VBDL to maintain data retention, a multiplexer (mux) can be used to set a LDL to the selected VBDL, for example, VBDL=0.2 V with a ones voltage =1 V and a zeros voltage =0V in a 3D DRAM. For best retention, VBLD can be in a range from about 100 mV to 300 mV. The mux can be used to disconnect the LDL from the GDL and the SA and bias it at a VBDL to optimize retention. However, for a read operation, with the local reference set at VBDL that is different from the voltage halfway between the ones volage and the zero voltages, the window for the sense operation of the read operation is not centered since the ones margin is larger than the zeros margin.

In various embodiments, to overcome difference in capacitance between a data LDL and its corresponding reference LDL, an amount of charge that is dumped onto the reference LDL can be adjusted. The adjustment can compensate for the mismatch in the unbalanced capacitance between the data LDL and the reference LDL. The adjustment can be provided by moving the voltage on the reference LDL from the idle LDL voltage that centers the window for sensing a one or a zero. A memory device can be constructed to implement a window centering scheme to add charge to the reference side of a SA such that an operational window is centered between a voltage for a zero and a voltage for a one on the reference side of the SA. A 3D DRAM device can be constructed to selectively apply an idle bias to a LDL having a voltage in a range to optimize data retention or a reference voltage to the LDL to bias the LDL to a centering voltage.

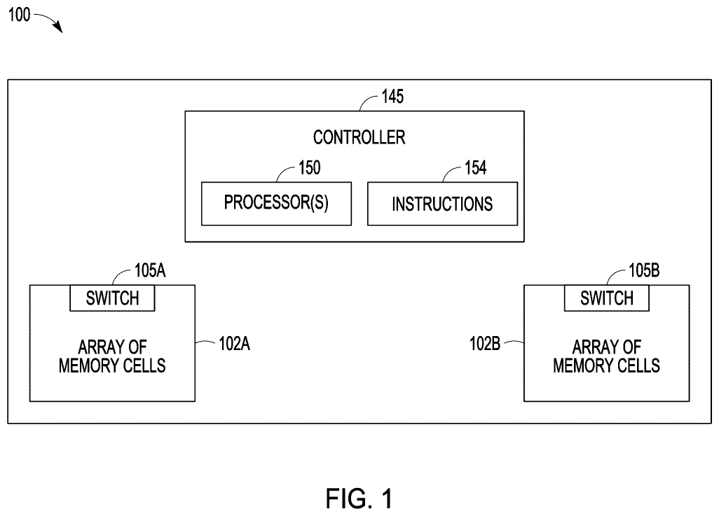

FIG. 1 is a block diagram of components of an embodiment of an example 3D DRAM device 100 implementing a control technique for a window for data access. 3D DRAM device can include a controller 145 to control multiple arrays of memory cells. Controller 145 can include one or more processors 150 that can execute instructions 154 to operate the multiple arrays of memory to execute data operations on the multiple arrays. 3D DRAM device 100 can include at least array 102A of memory cells and array 102B of memory cells. Array 102A and array 102B can be structured to store data in memory cells with WLs to select memory cells to which data is written or from which data is read. Array 102A and array 102B can be structured having the same design. Data is written to/read from the memory cells by LDLs coupled to the memory cells.

Controller 145 can operate on array 102A and 102B selected as either as a data array or a reference array. Controller 145 can change selection of array 102A and 102B as a data array or a reference array, depending on address information received by 3D DRAM 100 from an external host. In a read operation, when a read command is directed to 3D DRAM device 100 that includes an address of array102A for data, controller 145 can operate array 102A as a data array and array 102B as a reference array. With array 102A selected as the data array of the read operation, data of an identified memory cell can be transferred to a LDL of array 102A coupled to the memory cell for sensing. A LDL in array 102B, selected as a reference array, can be set as a reference LDL by controller 145 and a switch 105B can be actuated to change the voltage on the reference LDL in array 102B from VBLD of 3D DRAM 100 to LDL reference voltage (VLDLREF) prior to sensing for the read operation, with the memory cells coupled to the reference LDL maintained in an idle status. VLDLREF can be a voltage to a LDL of a 3D DRAM that is centered between a voltage for a zero and a voltage for a one. Switch 105B can be located at an edge of array 102B within array 102B or exterior to array 102B.

In a read operation, when a read command is directed to 3D DRAM device 100 that includes an address of array102B for data, controller 145 can operate array 102B as a data array and array 102A as a reference array. With array 102B selected as the data array of the read operation, data of an identified memory cell can be transferred to a LDL of array 102B coupled to the memory cell for sensing. A LDL in array 102A, selected as a reference array, can be set as a reference LDL by controller 145 and a switch 105A can be actuated to change the voltage on the reference LDL in array 102A from VBLD to a VLDLREF prior to sensing for the read operation, with the memory cells coupled to the reference LDL of array 102B maintained in an idle status. Switch 105A can be located at an edge of array 102A within array 102A or exterior to array 102A.

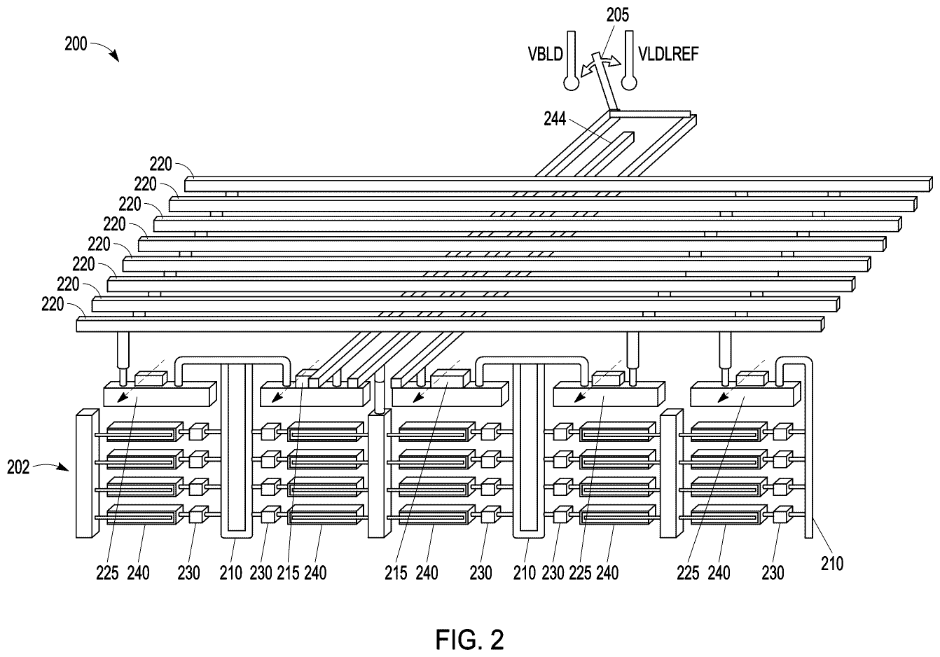

FIG. 2 illustrates a cross-sectional view of an embodiment of an example 3D DRAM device 200 having an array 202 of memory cells coupled to a switch 205. 3D DRAM device 200 can be implemented as 3D DRAM device 100 of FIG. 1. Array 202 can be implemented as array 102A or array 102B of 3D DRAM device 100 and can include memory cells, where each memory cell includes an access transistor coupled to a capacitor 240. FIG. 2 shows a portion of array 202 and does not show electric isolation regions or the access transistors for ease of presentation on the relationship of other components of 3D DRAM device 200 coupled to access transistors. WLs 230 are coupled to gates of access transistors, where the access transistors are coupled to capacitors 240 and to LDLs 210. Groups of capacitors 240 are coupled to a plate 244 that couples the group of capacitors 240 to a reference voltage, which can be, but is not limited to, a ground voltage. LDLs 210 are coupled to GDLs 220 by muxes 225. Muxes 225 can be operated by a controller such as controller 145 of 3D DRAM device to select one LDL of multiple LDLs to be conductively coupled to one GDL. With an access transistor in an on-state via a voltage on an WL 230 and a conductive path from a LDL, corresponding to the WL 230, to a GDL 220 provided by a mux 225, GDL 220 can provide a voltage to sensing circuitry.

Switch 205 is coupled to bleeder supply circuits 215 that are coupled to LDLs 210 to provide a voltage to one or more LDLs 210. Switch 205 can be coupled to one of multiple voltage sources. In the architecture of 3D DRAM device 200, switch 205 provides selective coupling to two voltage sources. The two voltage sources can be voltage sources or nodes coupled to voltage sources, where one voltage source provides VBLD and the other voltage source provides VLDLREF. VBLD can be a determined voltage to apply to a LDL to optimally maintain data retention in 3D DRAM device 200 and a VLDLREF can be a determined voltage to apply to a LDL to provide a read window centered between a voltage for a zero and a voltage for a one. Switch 205 within 3D DRAM device 200 can be located at an edge of array 202 within array 202 or external to array 202.

In the example architecture of 3D DRAM device 200, switch 205 is coupled to two bleeder supply circuits 215 for two LDLs 210. With N LDLs 210, N being even, such an architecture can use N/2 switches 205. A similar architecture can be structured with a switch 205 coupled to one bleeder supply circuit 215 for each LDL 210. A similar architecture can be structured with a switch 205 coupled to more than two bleeder supply circuits 215, with a reduced number of switches 205 compared to coupling to two bleeder supply circuits.

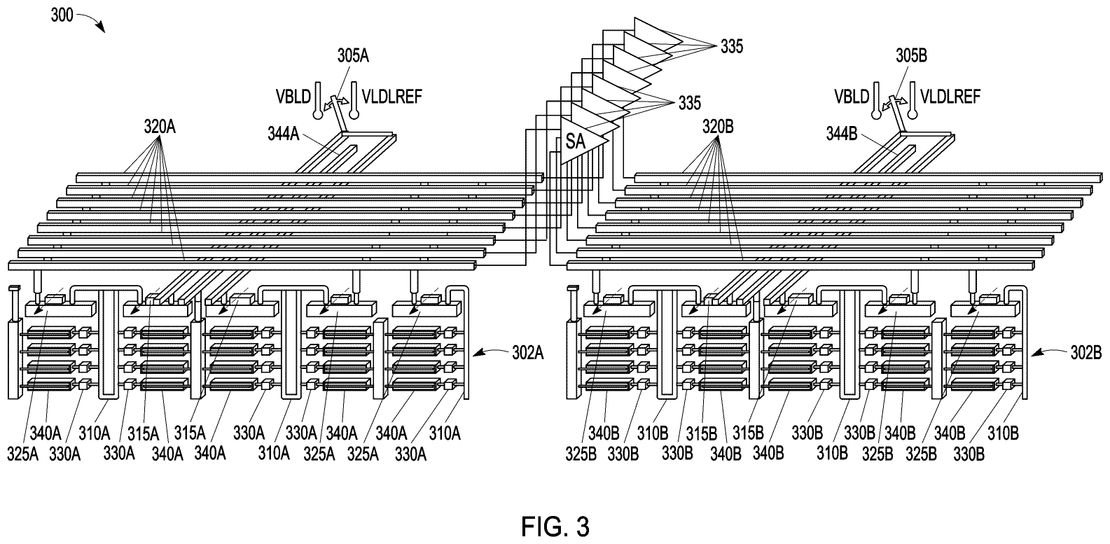

FIG. 3 illustrates a cross-sectional view of an embodiment of an example 3D DRAM device 300 having an array 302A of memory cells coupled to a switch 305A and an array 302B of memory cells coupled to a switch 305B. 3D DRAM device 300 can be implemented as 3D DRAM device 100 of FIG. 1. Each of array 302A and array 302B can be implemented similar or identical to 3D DRAM device 200 of FIG. 2. Arrays 302A and 302B can be implemented as arrays 102A and 102B of 3D DRAM device 100.

Array 302A can include memory cells, where each memory cell includes an access transistor coupled to a capacitor 340A. FIG. 3 shows a portion of array 302A and does not show electric isolation regions or the access transistors for ease of presentation on the relationship of other components of 3D DRAM device 300 coupled to access transistors. WLs 330A are coupled to gates of access transistors, where the access transistors are coupled to capacitors 340A and to LDLs 310A. Groups of capacitors 340A are coupled to a plate 344A that couples the group of capacitors 340A to a reference voltage, which can be, but is not limited to, a ground voltage. LDLs 310A are coupled to GDLs 320A by muxes 325A. Muxes 325A can be operated by a controller such as controller 145 of 3D DRAM device to select one LDL of multiple LDLs to be conductively coupled to one GDL. With an access transistor in an on-state via a voltage on an WL 330A and a conductive path from a LDL, corresponding to the WL 330A, to a GDL 320A provided by a mux 325A, GDL 320A can provide a voltage to an SA 335.

Switch 305A is coupled to bleeder supply circuits 315A that are coupled to LDLs 310A to provide a voltage to one or more LDLs 310A. Switch 305A can be coupled to one of multiple voltage sources. In the architecture of 3D DRAM device 300, switch 305A provides selective coupling to two voltage sources. The two voltage sources can be voltage sources or nodes coupled to voltage sources, where one voltage source provides VBLD and the other voltage source provides VLDLREF. VBLD can be a determined voltage to apply to a LDL to optimally maintain data retention in 3D DRAM device 300 and a VLDLREF can be a determined voltage to apply to a LDL to provide a read window centered between a voltage for a zero and a voltage for a one. Switch 305A within 3D DRAM device 300 can be located at an edge of array 302A within array 302A or external to array 302A.

Array 302B can include memory cells, where each memory cell includes an access transistor coupled to a capacitor 340B. FIG. 3 shows a portion of array 302B and does not show electric isolation regions or the access transistors for ease of presentation on the relationship of other components of 3D DRAM device 300 coupled to access transistors. WLs 330B are coupled to gates of access transistors, where the access transistors are coupled to capacitors 340B and to LDLs 310B. Groups of capacitors 340B are coupled to a plate 344B that couples the group of capacitors 340B to a reference voltage, which can be, but is not limited to, a ground voltage. LDLs 310B are coupled to GDLs 320B by muxes 325B. Muxes 325B can be operated by a controller such as controller 145 of 3D DRAM device to select one LDL of multiple LDLs to be conductively coupled to one GDL. With an access transistor in a on state via a voltage on an WL 330B and a conductive path from a LDL, corresponding to the WL 330B, to a GDL 320B provided by a mux 325B, GDL 320B can provide a voltage to sensing circuitry.

Switch 305B is coupled to bleeder supply circuits 315B that are coupled to LDLs 310B to provide a voltage to one or more LDLs 310B. Switch 305B can be coupled to one of multiple voltage sources. In the architecture of 3D DRAM device 300, switch 305B provides selective coupling to two voltage sources. The two voltage sources can be voltage sources or nodes coupled to voltage sources, where one voltage source provides VBLD and the other voltage source provides VLDLREF. VBLD can be a determined voltage to apply to LDL to optimally maintain data retention in 3D DRAM device 300 and VLDLREF can be a determined voltage to apply to a LDL to provide a read window centered between a voltage for a zero and a voltage for a one. Switch 305B within 3D DRAM device 300 can be located at an edge of array 302B on array 302B external to array 302B.

3D DRAM device 300 includes SAs 335. Each SA 335 has an input from a GDL 320A of array 302A and an input from a GDL 320B of array 302B. One of array 302A or array 302B is operatively selected to be a data array, depending on address of memory cells to be accessed with data, and the other one of array 302A or array 303B is operatively selected to be a reference array. Selection can be made by a controller similar to controller 145 of 3D DRAM 100. The switch of the selected reference array can operatively select VLDLREF to bias a LDL of the reference array during a read operation on data of the selected data array, where memory cells of the selected reference array are held in an idle state. To center the zeros-ones window for the LDL of the reference array, VLDLREF can be applied to the LDL of the reference array with a mux for the LDL off, prior to initiating an activation (ACT) operation. An ACT operation activates a row by driving a selected WL high and sensing data in cells on the activated row. The data of the selected data array is provided to a SA 335 via a GDL of the selected data array by the LDL of the selected data array for sensing with respect to a voltage from the GDL of the reference array coupled to the LDL of the selected reference array. In a precharge (PRE) operation, the LDL of the selected data array is driven to a voltage for a zero or a voltage for a one, depending on the data in the SA 335. In a PRE operation, a row is closed by turning on a digit line mux (DLMUX), driving data in sense amplifier latches onto the corresponding LDLs, and then turning off the row.

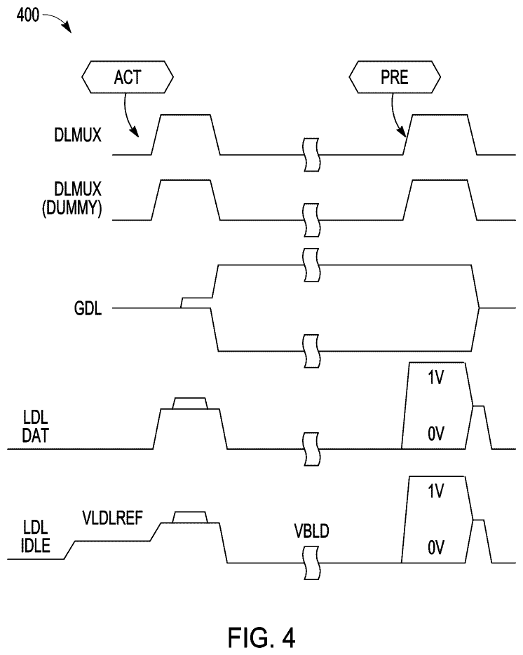

FIG. 4 illustrates an embodiment of an example procedural flow for window centering using a switch to provide a VLDLREF to a reference LDL for a data LDL operation. In an ACT operation, a reference LDL (idle LDL), which is in an idle state, is charged to VLDLREF through a bleeder supply circuit before a digit line mux (DLMUX) for reference LDL, which is a dummy DLMUX for the operation, turns on and before a DLMUX for a data LDL turns on. Reference LDL can be charged during a threshold voltage compensation, which is a technique for compensating for threshold mismatch. The bleeder supply circuit that provides VLDLREF is turned off and the DLMUX for the data LDL and the dummy DLMUX are turned on to charge the LDL to its corresponding GDL, which is at about a midpoint voltage that can be about 0.5V, to latch the data to a SA to which the GDL is coupled. Rather than shifting the reference LDL relative to data LDL as shown in FIG. 4, the data LDL can be shifted relative to the reference LDL. The DLMUX for the data LDL and the dummy DLMUX are turned off, and the data LDL and the idle LDL are biased at a lower voltage of VBLD to maximize retention. In a PRE operation, the data LDL is driven to a voltage of a zero or a voltage for a one, depending on the data in the SA. In various applications, a 3D DRAM device similar to 3D DRAM device 300 of FIG. 3 and the above example procedural flow can be used with a single reference LDL via a single reference DLMUX or with multiple reference LDLS via multiple reference DLMUXs.

The procedural flow of FIG. 4 can provide a technique to add charge to a reference GDL by adjusting VLDLREF to allow window centering prior to data sensing. VLDLREF can be trimmed for process, voltage, and temperature (PVT) to allow deadband centering across PVT corners. A corner refers to an imaginary region for specific performance of the circuits at each of its corners. Each corners can be an extreme limit that specifies a performance boundary condition for the design under consideration. Process corners represent extremes of fabrication process parameter variations for a fabricated circuit. When the parameters of an IC device are set in such a way that the device operates fast then it is known as a fast corner. A single circuit can perform differently for each process corner. The testing of the circuit performance at each corner is termed as a characterization. Dead band is a range through which an input can be varied without initiating an observable response. In fabrication, values of VLDLREF for different characterizations can be determined from deadband centering. A determined value can be incorporated for a voltage source or node to a voltage source node for a switch for 3D DRAM as taught herein. In operation, VLDLREF can be adjusted with the different values of VLDLREF.

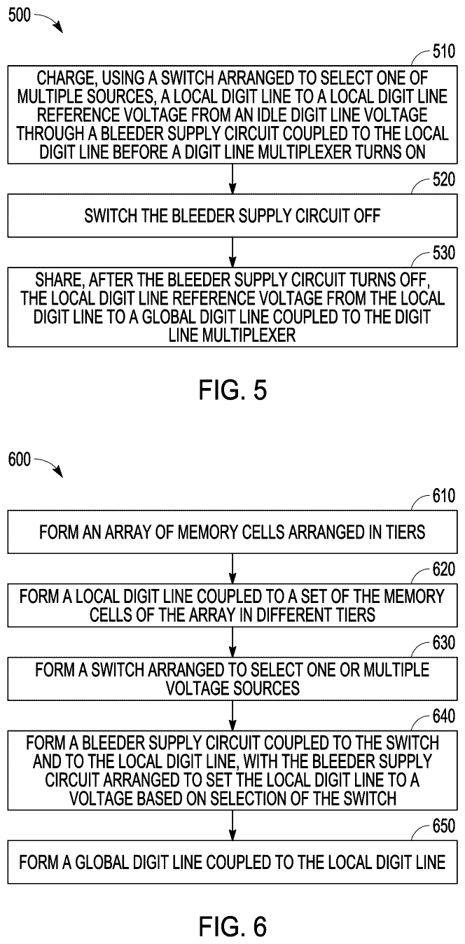

FIG. 5 is a flow diagram of features of an embodiment of a method 500 of operating a 3D memory device. The 3D memory device can be a 3D DRAM. At 510, using a switch arranged to select one of multiple sources, a LDL is charged to a LDL reference voltage from an idle digit line voltage through a bleeder supply circuit before a DLMUX turns on. The bleeder supply circuit is coupled to the LDL. The LDL is coupled to the digit line multiplexer and coupled to a set of memory cells in different tiers of an array of memory cells of the three-dimensional memory device.

At 520, the bleeder supply circuit is switched off. At 530, after the bleeder supply circuit turns off, the LDL reference voltage is shared from the LDL to a GDL coupled to the DLMUX. The LDL can be precharged after sharing the LDL reference voltage.

Variations of method 500 or methods similar to method 500 can include a number of different embodiments that may be combined depending on the application of such methods or the architecture or process flow of an integrated circuit for which such methods are implemented. Such methods can include maintaining the memory cells of the set of memory cells in an idle state during charging the LDL, switching the bleeder supply circuit off, sharing the digit line multiplexer, and precharging of the LDL. The memory cells of the set of memory cells can be maintained in the idle state by maintaining access transistors of the memory cells of the set of memory cells off via applying the appropriate voltages on corresponding WLs to the access transistors.

Variations of method 500 can include, with the GDL operating as a reference GDL, adding charge to the GDL by adjusting the LDL reference voltage to allow window centering prior to sensing a data GDL for which the GDL is being used as reference GDL. Variations can include trimming the LDL reference voltage for process, voltage, and temperature variations to allow dead band centering across corners of the variations.

FIG. 6 is a flow diagram of an embodiment of an example method 600 of forming a 3D DRAM device. At 610, an array of memory cells arranged in tiers is formed. At 620, a LDL is formed coupled to a set of the memory cells of the array in different tiers. At 630, a switch is formed arranged to select one of multiple voltage sources. At 640, a bleeder supply circuit is formed coupled to the switch and to the LDL. The bleeder supply circuit is arranged to set the LDL to a voltage based on selection of the switch. A GDL is formed coupled to the LDL. A digit line multiplexer can be formed coupling the LDL to the GDL.

Variations of method 600 or methods similar to method 600 can include a number of different embodiments that may be combined depending on the application of such methods or the architecture or process flow of an integrated circuit for which such methods are implemented. Such methods can include forming a second array of memory cells structured in the same manner as the array of memory cells. A SA can be formed with the GDL coupled to an input of the SA. A second GDL for the second array can be coupled to a second input of the SA.

Variations of method 600 or methods similar to method 600 can include forming a controller arranged to direct a switch to the second array to operate the second GDL as a data GDL. The controller can be arranged to direct the switch to the array to operate the array with the GDL as a reference GDL.

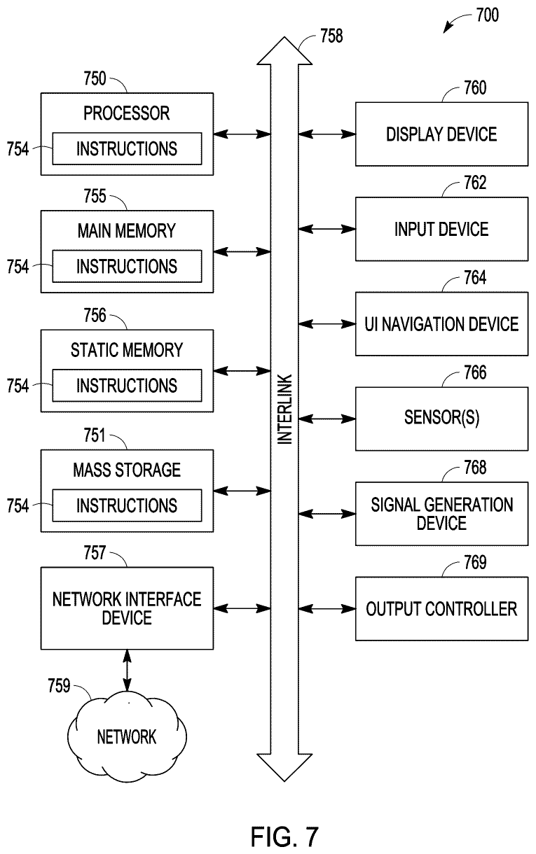

FIG. 7 illustrates a block diagram of an example machine 700 having one or more embodiments of memory components discussed herein. In alternative embodiments, machine 700 may operate as a standalone device or may be connected (e.g., networked) to other machines. In a networked deployment, machine 700 may operate in the capacity of a server machine, a client machine, or both in server-client network environments. In an example, machine 700 may act as a peer machine in peer-to-peer (P2P) (or other distributed) network environment. Machine 700 may be a personal computer (PC), a tablet PC, a set-top box (STB), a personal digital assistant (PDA), a mobile telephone, a web appliance, an IoT device, automotive system, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform one or more of methodologies such as, but not limited to, cloud computing, software as a service (SaaS), other computer cluster configuration services, or controlling machine actions using stored instructions or data. Example machine 700 can include one or more 3D memory devices having a mechanism for centering a window a voltage for a zero and a voltage for a one for memory access operations. The one or more 3D memory devices can be structured similar to features as discussed with respect to the 3D DRAM devices of FIGS. 1-3.

Machine (e.g., computer system) 700 may include a hardware processor 750 (e.g., a CPU, a GPU, a hardware processor core, or any combination thereof), a main memory 755 and a static memory 756, some or all of which may communicate with each other via an interlink (e.g., bus) 758. Machine 700 may further include a display device 760, an alphanumeric input device 762 (e.g., a keyboard), and a user interface (UI) navigation device 764 (e.g., a mouse). In an example, display device 760, alphanumeric input device 762, and UI navigation device 764 may be a touch screen display. Machine 700 may additionally include a mass storage (e.g., drive unit) 751, a signal generation device 768 (e.g., a speaker), a network interface device 757, and one or more sensors 766, such as a global positioning system (GPS) sensor, compass, accelerometer, or other sensor. Machine 700 may include an output controller 769, such as a serial (e.g., USB, parallel, or other wired or wireless (e.g., infrared (IR), near field communication (NFC), etc.) connection to communicate or control one or more peripheral devices (e.g., a printer, card reader, etc.).

Machine 700 may include a machine-readable medium on which is stored one or more sets of data structures or instructions 754 (for example, software or microcode) embodying or utilized by machine 700. Instructions 754 may also reside, completely or at least partially, within main memory 755, within static memory 756, within mass storage 751, or within hardware processor 750 during execution thereof by machine 700. In an example, one or any combination of hardware processor 750, main memory 755, static memory 756, or mass storage 751 may constitute machine-readable medium. Machine-readable medium can be a single medium or multiple media (e.g., a centralized or distributed database, or associated caches and servers) configured to store one or more instructions 754.

The term “machine-readable medium” may include any medium that is capable of storing instructions for execution by machine 700 and that cause machine 700 to perform any one or more of the techniques for which machine 700 is implemented. Non-limiting machine-readable medium examples may include solid-state memories, and optical and magnetic media. Non-volatile machine-readable medium may include semiconductor memory devices such as EPROM, EEPROM, and flash memory devices; magnetic disks, such as internal hard disks and removable disks; magneto-optical disks; and compact disc-ROM (CD-ROM) and digital versatile disc-read only memory (DVD-ROM) disks. Volatile machine-readable medium may include (RAM), DRAM, SRAM, or SDRAM.

Instructions 754 (e.g., software, programs, microcode, an operating system (OS), etc.) or other data stored on mass storage 751 can be accessed by main memory 755 for use by processor 750. Main memory 755 (e.g., DRAM) is typically fast, but volatile, and thus a different type of storage than mass storage 751 (e.g., an SSD), which is suitable for long-term storage, including while in an “off” condition. Instructions 754 or data in use by a user or machine 700 are typically loaded in main memory 755 for use by processor 750. When main memory 755 is full, virtual space from mass storage 751 can be allocated to supplement main memory 755; however, because mass storage 751 is typically slower than main memory 755, and write speeds are typically at least twice as slow as read speeds, use of virtual memory can greatly reduce user experience due to storage device latency (in contrast to main memory 755, e.g., DRAM). Further, use of mass storage 751 for virtual memory can greatly reduce the usable lifespan of mass storage 751.

Storage devices optimized for mobile electronic devices, or mobile storage, traditionally include MMC solid-state storage devices (e.g., micro Secure Digital (microSD™) cards, etc.). MMC devices include a number of parallel interfaces (e.g., an 8-bit parallel interface) with a host device and are often removable and separate components from the host device. In contrast, eMMC™ devices are attached to a circuit board and considered a component of the host device, with read speeds that rival SATA based SSD devices. However, demand for mobile device performance continues to increase, such as to fully enable virtual or augmented-reality devices, utilize increasing networks speeds, etc. In response to this demand, storage devices have shifted from parallel to serial communication interfaces. UFS devices, including controllers and firmware, communicate with a host device using a low-voltage differential signaling (LVDS) serial interface with dedicated read/write paths, further advancing greater read/write speeds.

Instructions 754 may further be transmitted or received over a network 759 using a transmission medium via network interface device 757 utilizing any one of a number of transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.11 family of standards known as Wi-Fi®, IEEE 802.16 family of standards known as WiMax®), IEEE 802.15.4 family of standards, peer-to-peer (P2P) networks, among others. In an example, network interface device 757 may include one or more physical jacks (e.g., Ethernet, coaxial, or phone jacks) or one or more antennas to connect to the communications network 726. In an example, network interface device 757 may include a plurality of antennas to wirelessly communicate using at least one of single-input multiple-output (SIMO), multiple-input multiple-output (MIMO), or multiple-input single-output (MISO) techniques. The term “transmission medium” shall be taken to include any tangible medium that is capable of transporting instructions for execution by machine 700 or data to or from machine 700. The transportation can include using digital or analog communications signals that can be transmitted over the transmission medium to facilitate communication of such software or data.

The following are example embodiments of devices and methods, in accordance with the teachings herein.

An example three-dimensional memory device 1 can comprise an array of memory cells, the memory cells arranged in tiers; a LDL coupled to a set of the memory cells of the array in different tiers; a switch arranged to select one of multiple voltage sources; a bleeder supply circuit coupled to the switch and to the LDL, the bleeder supply circuit arranged to set the LDL to a voltage based on selection of the switch; and a GDL coupled to the LDL.

An example three-dimensional memory device 2 can include features of example three-dimensional memory device 1 and can include the multiple voltage sources to include an idle digit line voltage source and a LDL reference voltage source.

An example three-dimensional memory device 3 can include features of any of the preceding example three-dimensional memory devices and can include a digit line multiplexer coupling the LDL to the GDL.

An example three-dimensional memory device 4 can include features of any of the preceding example three-dimensional memory devices and can include another bleeder circuit coupled to the switch and to another digit line, with the other digit line coupled to the GDL.

An example three-dimensional memory device 5 can include features of any of the preceding example three-dimensional memory devices and can include a controller to control the switch in response to identification of a memory cell in a write or read operation.

An example three-dimensional memory device 6 can include features of any of the preceding example three-dimensional memory devices and can include a controller to: select the LDL of the array as a reference to another LDL of another array coupled to a GDL for the other array in a data operation on the other LDL; and maintain memory cells of the array in an idle state during the data operation on the other digit line.

An example three-dimensional memory device 7 can include features of example three-dimensional memory device 6 and any of the preceding example three-dimensional memory devices and can include the array and the other array being directly adjacent each other.

An example three-dimensional memory device 8 can include features of example three-dimensional memory device 6 and any of the preceding example three-dimensional memory devices and can include the LDL and the other LDL coupled as inputs to a SA.

An example three-dimensional memory device 9 can include features of example three-dimensional memory device 6 and any of the preceding example three-dimensional memory devices and can include the array and the other array being constructed to store data and the controller being configured is select one of the array or the other array as reference for a read or write operation of data on the other one of the array or the other array, based on an address of the read or write operation.

An example three-dimensional memory device 10 can include features of any of the preceding example three-dimensional memory devices and can include the switch being located at an edge of the array.

In an example three-dimensional memory device 11, any of the three-dimensional memory devices of example three-dimensional memory devices 1 to 10 may include three-dimensional memory devices incorporated into an electronic apparatus further comprising a host processor or memory controller and a communication bus extending between the host processor/memory controller and the three-dimensional memory device.

In an example three-dimensional memory device 12, any of the three-dimensional memory devices of example three-dimensional memory devices 1 to 11 may be modified to include any structure presented in another of example three-dimensional memory device 1 to 11.

In an example three-dimensional memory device 13, any apparatus associated with the three-dimensional memory devices of example three-dimensional memory devices 1 to 12 may further include a machine-readable storage device configured to store instructions as a physical state, wherein the instructions may be used to perform one or more operations of the apparatus.

In an example three-dimensional memory device 14, any of the three-dimensional memory devices of example three-dimensional memory devices 1 to 13 may be operated in accordance with any of the below example methods of forming a three-dimensional memory device 1 to 10 and methods of operating a memory device 1 to 8.

An example method 1 of operating a three-dimensional memory device can comprise charging, using a switch arranged to select one of multiple sources, a LDL to a LDL reference voltage from an idle digit line voltage through a bleeder supply circuit coupled to the LDL before a digit line multiplexer turns on, the LDL coupled to the digit line multiplexer and coupled to a set of memory cells in different tiers of an array of memory cells of the three-dimensional memory device; switching the bleeder supply circuit off; and sharing, after the bleeder supply circuit turns off, the LDL reference voltage from the LDL to a GDL coupled to the digit line multiplexer.

An example method 2 of operating a three-dimensional memory device can include features of example method 1 of operating a three-dimensional memory device and can include precharging the LDL after sharing the LDL reference voltage.

An example method 3 of operating a three-dimensional memory device can include features of example method 2 of operating a three-dimensional memory device and any of the preceding example methods of operating a three-dimensional memory device and can include maintaining the memory cells of the set of memory cells in an idle state during charging the LDL, switching the bleeder supply circuit off, sharing the digit line multiplexer, and precharging of the LDL.

An example method 4 of operating a three-dimensional memory device can include features of example method 2 of operating a three-dimensional memory device and any of the preceding example methods of operating a three-dimensional memory device and can include maintaining the memory cells of the set of memory cells in the idle state includes maintaining access transistors of the memory cells of the set of memory cells off via voltages on corresponding WLs.

An example method 5 of operating a three-dimensional memory device can include features of any of the preceding example methods of operating a three-dimensional memory device and can include adding charge to the GDL, with the GDL operating as a reference GDL, by adjusting the LDL reference voltage to allow window centering prior to sensing a data GDL for which the GDL is being used as reference GDL.

An example method 6 of operating a three-dimensional memory device can include features of any of the preceding example methods of operating a three-dimensional memory device and can include trimming the LDL reference voltage for process, voltage, and temperature variations to allow dead band centering across corners of the variations.

In an example method 7 of operating a three-dimensional memory device, any of the example methods 1 to 6 of operating a three-dimensional memory device may be performed in operating an electronic apparatus comprising a host processor and a communication bus extending between the host processor and a memory system.

In an example method 8 of operating a three-dimensional memory device, any of the example methods 1 to 7 of operating a three-dimensional memory device may be modified to include operations set forth in any other of example methods 1 to 7 of operating a three-dimensional memory device.

In an example method 9 of operating a three-dimensional memory device, any of the example methods 1 to 9 of operating a three-dimensional memory device may be implemented at least in part through use of instructions stored as a physical state in one or more machine-readable storage devices.

An example method 10 of operating a three-dimensional memory device can include features of any of the preceding example methods 1 to 9 of operating a three-dimensional memory device and can include performing functions associated with any features of example memory devices 1 to 14.

An example method 1 of forming a three-dimensional memory device can comprise forming an array of memory cells arranged in tiers; forming a LDL coupled to a set of the memory cells of the array in different tiers; forming a switch arranged to select one of multiple voltage sources; forming a bleeder supply circuit coupled to the switch and to the LDL, with the bleeder supply circuit arranged to set the LDL to a voltage based on selection of the switch; and forming a GDL coupled to the LDL.

An example method 2 of forming a three-dimensional memory device can include features of example method 1 of forming a three-dimensional memory device and can include forming a digit line multiplexer coupling the LDL to the GDL.

An example method 3 of forming a three-dimensional memory device can include features of any of the preceding example methods of forming a three-dimensional memory device and can include forming another array of memory cells structured in the same manner as the array of memory cells; forming a SA with the GDL coupled to an input of the SA; and coupling another GDL for the other array to another input of the SA.

An example method 4 of forming a three-dimensional memory device can include features of example method 3 of forming a three-dimensional memory device and any of the preceding example methods of forming a three-dimensional memory device and can include and can include forming a controller arranged to: direct a switch to the other array to operate the other GDL as a data GDL, and direct the switch to the array to operate the array with the GDL as a reference GDL.

In an example method 5, any of the example methods 1 to 4 of forming a three-dimensional memory device may be performed in forming an electronic apparatus further comprising a host processor and a communication bus extending between the host processor and a memory system.

In an example method 6 of forming a three-dimensional memory device, any of the example methods 1 to 5 of forming a three-dimensional memory device may be modified to include operations set forth in any other of example methods 1 to 5 of forming a three-dimensional memory device.

In an example method 7 of forming a three-dimensional memory device, any of the example methods 1 to 6 of forming a three-dimensional memory device may be implemented at least in part through use of instructions stored as a physical state in one or more machine-readable storage devices.

An example method 8 of forming a three-dimensional memory device can include features of any of the preceding example methods 1 to 7 of forming a three-dimensional memory device and can include performing functions associated with any features of example three-dimensional memory devices 1 to 14 and any features of example methods 1 to 10 of operating a three-dimensional memory device.

An example machine-readable storage device storing instructions, that when executed by one or more processors, cause a machine to perform operations, can comprise instructions to perform functions associated with any features of example three-dimensional memory devices 1 to 14 or perform form methods associated with any features of example methods 1 to 8 of forming a three-dimensional memory device or example methods 1 to 10 of operating a three-dimensional memory device.

Although specific embodiments have been illustrated and described herein, it will be appreciated by those of ordinary skill in the art that any arrangement that is calculated to achieve the same purpose may be substituted for the specific embodiments shown. Various embodiments use permutations and/or combinations of embodiments described herein. It is to be understood that the above description is intended to be illustrative, and not restrictive, and that the phraseology or terminology employed herein is for the purpose of description.

What is claimed is:

1. A three-dimensional memory device comprising:
an array of memory cells, the memory cells arranged in tiers;
a local digit line coupled to a set of the memory cells of the array in different tiers;
a switch arranged to select one of multiple voltage sources;
a bleeder supply circuit coupled to the switch and to the local digit line, the bleeder supply circuit arranged to set the local digit line to a voltage based on selection of the switch; and
a global digit line coupled to the local digit line.

2. The three-dimensional memory device of claim 1, wherein the multiple voltage sources include an idle digit line voltage source and a local digit line reference voltage source.

3. The three-dimensional memory device of claim 1, wherein the three-dimensional memory device includes a digit line multiplexer coupling the local digit line to the global digit line.

4. The three-dimensional memory device of claim 1, wherein the three-dimensional memory device includes another bleeder circuit coupled to the switch and to another digit line, with the other digit line coupled to the global digit line.

5. The three-dimensional memory device of claim 1, wherein the three-dimensional memory device includes a controller to control the switch in response to identification of a memory cell in a write or read operation.

6. The three-dimensional memory device of claim 1, wherein the three-dimensional memory device includes a controller to:
select the local digit line of the array as a reference to another local digit line of another array coupled to a global digit line for the other array in a data operation on the other local digit line; and
maintain memory cells of the array in an idle state during the data operation on the other digit line.

7. The three-dimensional memory device of claim 6, wherein the array and the other array are directly adjacent each other.

8. The three-dimensional memory device of claim 6, wherein the local digit line and the other local digit line are coupled as inputs to a sense amplifier.

9. The three-dimensional memory device of claim 6, wherein the array and the other array are constructed to store data and the controller is configured is select one of the array or the other array as reference for a read or write operation of data on the other one of the array or the other array, based on an address of the read or write operation.

10. The three-dimensional memory device of claim 1, wherein the switch is located at an edge of the array.

11. A method of operating a three-dimensional memory device, the method comprising:
charging, using a switch arranged to select one of multiple sources, a local digit line to a local digit line reference voltage from an idle digit line voltage through a bleeder supply circuit coupled to the local digit line before a digit line multiplexer turns on, the local digit line coupled to the digit line multiplexer and coupled to a set of memory cells in different tiers of an array of memory cells of the three-dimensional memory device;
switching the bleeder supply circuit off; and
sharing, after the bleeder supply circuit turns off, the local digit line reference voltage from the local digit line to a global digit line coupled to the digit line multiplexer.

12. The method of claim 11, wherein method includes precharging the local digit line after sharing the local digit line reference voltage.

13. The method of claim 12, wherein method includes maintaining the memory cells of the set of memory cells in an idle state during charging the local digit line, switching the bleeder supply circuit off, sharing the digit line multiplexer, and precharging of the local digit line.

14. The method of claim 13, wherein maintaining the memory cells of the set of memory cells in the idle state includes maintaining access transistors of the memory cells of the set of memory cells off via voltages on corresponding access lines.

15. The method of claim 11, wherein the method includes adding charge to the global digit line, with the global digit line operating as a reference global digit line, by adjusting the local digit line reference voltage to allow window centering prior to sensing a data global digit line for which the global digit line is being used as reference global digit line.

16. The method of claim 11, wherein the method includes trimming the local digit line reference voltage for process, voltage, and temperature variations to allow dead band centering across corners of the variations.

17. A method of forming a three-dimensional memory device, the method comprising:
forming an array of memory cells arranged in tiers;
forming a local digit line coupled to a set of the memory cells of the array in different tiers;
forming a switch arranged to select one of multiple voltage sources;
forming a bleeder supply circuit coupled to the switch and to the local digit line, with the bleeder supply circuit arranged to set the local digit line to a voltage based on selection of the switch; and
forming a global digit line coupled to the local digit line.

18. The method of claim 17, wherein the method includes forming a digit line multiplexer coupling the local digit line to the global digit line.

19. The method of claim 17, wherein the method includes:
forming another array of memory cells structured in the same manner as the array of memory cells;
forming a sense amplifier with the global digit line coupled to an input of the sense amplifier; and
coupling another global digit line for the other array to another input of the sense amplifier.

20. The method of claim 19, wherein the method includes forming a controller arranged to:
direct a switch to the other array to operate the other global digit line as a data global digit line; and
direct the switch to the array to operate the array with the global digit line as a reference global digit line.
